(19) United States
(12) Patent Application Publication
(10) Pub. No.: US 2010/0289121 A1
(43) Pub. Date: Nov. 18, 2010

(54) Chip-Level Access Control via Radioisotope Doping

(76) Inventor: Eric Hansen, Dallas, TX (US)

Correspondence Address: Eric Hansen, 3813 Wentwood, Dallas, TX, 75225, US

(21) Appl. No.: 12/465,869

(22) Filed: May 14, 2009

(51) Int. Cl. H01L 29/12; H01B 1/00; H01L 29/8605

(52) U.S. Cl. 257/536; 252/517; 257/610; 257/607; 257/E29.068; 257/E29.326

(57) ABSTRACT

A mechanism for changing the doping profile of semiconductor devices over time using radioisotope dopants is disclosed. This mechanism can be used to activate or deactivate a device based on the change in doping profile over time. The disclosure contains several possible dopants for common semiconductor substrates and discusses several simple devices which could be used to actuate a circuit. The disclosure further discloses a means for determining the optimal doping profile to achieve a transition in bulk electrical properties of a semiconductor at a specific time.

### BACKGROUND OF INVENTION

Controlling access to information and technology is an ongoing problem. Software methods are common, but once defeated the means to circumvent a software access control system is quickly and easily disseminated. Access control methods using physical impediments, such as locked doors, serve primarily to delay access. Controlling access when an attacker has full physical possession of a device is particularly difficult, as the attacker has unlimited time to defeat any access control system he encounters.

Limiting the access of end users has become increasingly important. In the entertainment world, digital copy protection has become widespread. Most software now comes with access control programs. More sophisticated programs incorporate physical keys or biometrics. For most purposes, this is enough.

One notable exception is military technology. Military technology, or technology that could be used for military purposes such as weapon design, is currently export controlled because of the difficulty in controlling who eventually has access to it. As a result, a bounty of products and innovations cannot be marketed overseas and many of our allies have limited access to our technology. This is particularly problematic when lack of advanced technology puts both our allies and our own soldiers at greater risk. At the same time, many military-grade devices are designed to function effectively for decades. Supplying our current allies with equipment that will still be useful in two decades could leave us with well-equipped foes.

### SUMMARY OF INVENTION

In order to address these and other issues, the present invention provides a mechanism by which semiconductor devices can be automatically and permanently deactivated by the passage of time.

In accordance with the invention, a semiconductor device is doped with a combination of impurities. Some of these impurities may be those typically used in semiconductor device fabrication, but at least one doped region will have high concentrations of radioisotope dopants that will change dopant type upon their radioactive decay. The resulting change in dopant type changes the number and type of carriers contributed to the semiconductor by the dopant. Once enough of the radioisotope dopants decay the characteristics of the semiconductor in that area will change. A change in semiconductor characteristics can cause a device to cease to function in a predictable way in a predictable interval. By integrating these radioisotope-doped devices into sensitive equipment or devices, manufacturers can insure that only those with a continuous stream of support and replacement parts can operate the device. This radioisotope-based deactivation mechanism cannot be hacked or circumvented and any device rendered inert by this mechanism can only be restored through the replacement of the deactivated chip.

### DETAILED DESCRIPTION

Semiconductors operating in typical conditions have approximately 10¹⁰ free carriers of each type (negatively charged electrons and positively charged holes) per cubic centimeter. In order to increase the number of carriers, impurities are intentionally added to the semiconductor, either during the initial manufacture of the wafer or later during a process called ion bombardment and implantation. Even a small concentration of dopants, such as 10¹¹ per cubic centimeter, can dramatically increase the number of free carriers and change which type of carrier dominates. Typically, semiconductor devices have dopant concentrations between 10¹¹ and 10¹⁹ dopants per cubic centimeter. Even at the high end of that range, approximately one of every thousand atoms in the crystal are dopant atoms.

The electrical properties of these dopant atoms are widely studied and well understood. Dopants normally fall into two categories based on how many electrons they can make available to the crystal relative to the atoms they displace in the lattice. Atoms that donate extra electrons into the lattice are called donors and when prevalent create n-type semiconductors. Atoms that capture electrons from the lattice are called acceptors and when prevalent create p-type semiconductors. Additionally, some dopants have ionization energies far from the edge of the band gap, giving rise to more complex properties. These deep impurities can act as n- or p-type dopants with lower ionization rates, as traps that can capture and release carriers, or otherwise alter the electrical properties of the semiconductor.

When p-type and n-type regions of semiconductor are next to each other, they form a structure called a p-n junction that is used in many semiconductor devices. P-n junctions act as diodes allowing current to flow in only one direction. If the n-type region or p-type region were to change into p-type or n-type respectively then current could flow in either direction. If both switched types then the junction would allow current to flow in the previously blocked direction and block current in the previously allowed direction.

Using this change in device property as a mechanism for disabling a device is straightforward. One can build a circuit depending on a voltage differential between two points and place a radioisotope-doped p-n junction between those two points. When the junction decays into a conductor, the voltage differential between the two points will drop and the rest of the circuit will malfunction. A similar mechanism utilizing a resistor that, over time, increased or decreased in conductivity could be used as well.

The property of a dopant in a lattice depends on the semiconductor. A dopant that is well ionized p-type in one type of semiconductor may be a deep impurity or an n-type dopant in another semiconductor. There are dozens of semiconductors currently in use or under research and the properties of dopants in all of these materials is not understood. Research is on-going in this field, with organic semiconductors being a particularly hot field. The methods taught by the present invention have application in all of these semiconductor systems.

Radioisotope dopants have four initial types: n-type, p-type, deep impurity, and substrate. When these dopants decay, they will decay into a specific other type of dopant: n-type, p-type, deep impurity, or substrate. Some pass through an intermediate stage in their decay, but the intermediate nuclide is so short-lived that its concentration in the lattice will be negligible compared to the concentrations of other dopants.

Table 1 (below) contains a partial listing of radioisotopes useful for the doping of silicon and germanium semiconductors. These examples are provided as a means for illustrating the invention and other materials and radioisotope dopants can be used in accordance with the invention.

TABLE 1
Various radioisotope dopants useful in the doping of Silicon and
Germanium semiconductors.

| | | | | Decay | | | |
|---|---|---|---|---|---|---|---|
| | | Dopant | Decay | Product | Decay | | Intermediate |
| Substrate | Dopant | Type | Product | Type | Mode | Half life | Stage |
| Ge | 68Ge | Substrate | 68Zn | 2x p-type | EC | 270d | 68Ga |
| Ge | 73As | n-type | 73Ge | Substrate | EC | 80d | None |
| Ge | 7Be | 2x p-type | 7Li | n-type | EC | 53d | None |
| Si | 49V | deep (p-type) | 49Ti | deep (n-type) | EC | 337d | None |
| Si | 54Mn | deep (n-type) | 54Fe | n-type | EC; B- | 312d | 54Cr |
| Si | 55Fe | n-type | 55Mn | deep (n-type) | EC | 2.73y | None |
| Si | 59Fe | n-type | 59Co | deep (p-type) | B- | 45.5d | None |
| Si | 56Co | deep (p-type) | 56Fe | n-type | EC | 77d | None |
| Si | 57Co | deep (p-type) | 57Fe | n-type | EC | 271d | None |
| Si | 58Co | deep (p-type) | 58Fe | n-type | EC | 70d | None |
| Si | 75Se | deep (n-type) | 75As | n-type | EC | 120d | None |
| Ge | 75Se | deep (n-type) | 75As | n-type | EC | 120d | None |
| Si | 123Sn | deep | 123Sb | n-type | B- | 129d | None |
| Ge | 123Sn | deep | 123Sb | n-type | B- | 129d | None |
| Si | 113Sn | deep | 113In | p-type | EC | 115d | None |
| Ge | 113Sn | deep | 113In | p-type | EC | 115d | None |
| Ge | 125Sb | n-type | 125Te | deep (n-type) | B- | 2.75y | None |
| Si | 125Sb | n-type | 125Te | deep (n-type) | B- | 2.75y | None |

Dopant concentration is one of the most important factors impacting device performance. Dopant concentrations significantly below the intrinsic carrier concentration of the semiconductor substrate have little effect on the properties of the semiconductor. Intrinsic carrier concentration is a function of the material's density of states function, its bandgap, and temperature. A dopant concentration effective for low temperature operation of a semiconductor device may have little or no effect at higher temperatures. Common semiconductors have intrinsic carrier concentrations at normal operating temperatures between 10⁷ and 10¹² carriers per cubic centimeter. Silicon, by far the most common semiconductor in commercial use, has around 10¹⁰ of each type of carrier at room temperature.

Dopants in very high quantities can result in undesirable changes in the semiconductor substrate's electronic and mechanical properties. In common semiconductors, dopants are rarely useful in concentrations greater than 10¹⁹ or 10²⁰ dopants per cubic centimeter.

Typically, dopants are used in concentrations between 10¹¹ and 10¹⁸ dopants per centimeter cubed.

Among the radioisotope dopant-induced changes contemplated by this invention are changes from one conductor type to another within the radioisotope-doped region (e.g. n-type to p-type) and the increase or decrease in conductivity of a radioisotope-doped region.

The behavior of radioactive species is well understood. The quantity of an initial radioactive sample remaining after a given time is proportional to the initial quantity and a decaying exponential function incorporating the radioactive species' half life.

The present invention contemplates using these radioisotope dopants to change the bulk properties of semiconductors. As a result the carrier concentrations vary as a function of time. Assuming the n-type and p-type dopants are fully ionized and deep impurities are negligibly ionized, Table 2 below provides the time-dependent concentration profiles for radioisotope-doped semiconductors.

TABLE 2
Time-dependent carrier concentrations arising from radioisotope doping of semiconductors.

| Radioisotope | | N → substrate | | P → substrate | Substrate or | Substrate or |
|---|---|---|---|---|---|---|
| type | N → p | or deep | P → n | or deep | deep → n | deep → p |
| Electron carrier | N_{D} − N_{A} + 2R(t) − R₀ | N_{D} − N_{A} + R(t) | N_{D} − N_{A} + R₀ − 2R(t) | N_{D} − N_{A} − R(t) | N_{D} − N_{A} + R₀ − R(t) | N_{D} − N_{A} − R₀ + R(t)) |
| concentration | | | | | | |
| (when | | | | | | |
| prevalent) | | | | | | |
| Hole carrier | N_{A} − N_{D} + R₀ − 2R(t) | N_{A} − N_{D} − R(t) | N_{A} − N_{D} + 2R(t) − R₀ | N_{A} − N_{D} + R(t) | N_{A} − N_{D} − R₀ + R(t) | N_{A} − N_{D} + R₀ − R(t) |
| concentration | | | | | | |
| (when | | | | | | |
| prevalent) | | | | | | |
| n [symbol] p transition | R(t) = .5(N_{A} + R₀ − | R(t) = N_{A} − N_{D} | R(t) = .5(N_{D} + R₀ − | R(t) = N_{D} − N_{A} | R(t) = N_{D} + R₀ − N_{A} | R(t) = N_{A} + R₀ − N_{D} |
| | N_{D}) | | N_{A}) | | | |

N_{A} and N_{D} are the non-radioisotope dopants present.
R₀ is the initial concentration of radioisotope dopants and
R(t) is the remaining concentration of radioisotope dopants after time t.

Using the above table, and the radioactive decay function of the desired radioisotope species, doping profiles that change over time can be created and calibrated to so that transitions in bulk material properties occur at specific future times. Devices relying on these bulk properties can be implemented to start or stop functioning when that threshold is crossed. Multiple radioisotope dopants could also be combined to produce more complex effects.

The potential combinations of radioisotope dopant and semiconductor are vast, with dozens of semiconductors each with dozens of potential dopants, the inventor prefers germanium doped with 68Ge, 73As, or 7Be or silicon doped with 123Sn, 113Sn, or 125Sb. These combinations yield particularly strong transitions and a wide range of dopant types and half lives, affording great flexibility in the timing, type, and number of transitions possible.

While the terms used herein should be familiar to one skilled in the art, a few terms should be explicitly defined for clarity. A dopant is an atomic impurity in a semiconductor introduced either when the semiconductor crystal was fabricated or at some later time. Doping is the process of introducing these impurities. A semiconductor crystal is doped with a dopant when it contains that dopant, typically in concentrations between 10¹⁰ and 10²⁰ dopant atoms per cubic centimeter of semiconductor.

While the invention has been prescribed with reference to specific semiconductors and dopants, those skilled in the art will appreciate that certain substitutions, alterations, and omissions may be made to the embodiments without departing from the spirit of the invention. Accordingly, the foregoing description is meant to be exemplary only and should not limit the scope of the invention as set forth in the claims.

What is claimed is:

1. A semiconductor containing between 10¹⁰ and 10²⁰ radioactive dopants per cubic centimeter.

2. The semiconductor of claim 1 the radioactive dopants are nuclides of an element comprising the semiconductor.

3. The semiconductor of claim 1 where the radioactive dopant and its decay product have different ionization properties in the semiconductor.

4. The semiconductor of claim 1 where the radioactive dopant is ionized to create free electron carriers and its decay product is ionized to create hole carriers.

5. The semiconductor of claim 1 where the decay of said radioactive dopants causes a transition between n-type and p-type.

6. The semiconductor of claim 1 where the radioactive dopant is ionized to create hole carriers and its decay product is ionized to create electron carriers.

7. The semiconductor of claim 1 where the decay of said radioactive dopants causes a change in bulk resistivity.

8. The semiconductor of claim 1 where the radioactive dopant has a higher or lower ionization energy than its decay product.

9. A p-n junction comprising
a region of semiconductor doped with acceptors
a region of semiconductor doped with donors
at least one region doped with a radioactive dopant having different doping properties from its decay products.

10. The p-n junction of claim 9 where the radioactive dopant is an acceptor and its decay product is a donor.

11. The p-n junction of claim 9 where the radioactive dopant is a donor and its decay product is an acceptor.

12. The p-n junction of claim 9 where the radioactive dopant is a nuclide of a substrate atom and the decay product is a donor or acceptor.

13. The p-n junction of claim 9 where the radioactive dopant is a deep impurity and the decay product is a donor or an acceptor.

14. The p-n junction of claim 9 where the radioactive dopant is a donor or an acceptor and its decay product is a nuclide of a substrate atom.

15. The p-n junction of claim 9 where the radioactive dopant is a donor or an acceptor and its decay product is a deep impurity.

16. A resistor comprising
a region of semiconductor
a region doped with a radioactive dopant.

17. The resistor of claim 16 where the radioactive dopant yields few carriers and its decay product is readily ionized at the operating temperature.

18. The resistor of claim 16 where the radioactive dopant is readily ionized at the operating temperature and its decay product yields few carriers.

19. A circuit comprising at least one device that is doped with radioactive dopants, where said circuit is either closed or opened as a result of the dopant decay.
